(19) United States
(12) Patent Application Publication
(10) Pub. No.: US 2026/0100688 A1
(43) Pub. Date: Apr. 9, 2026

(54) ACOUSTIC WAVE DEVICE

(71) Applicant: Murata Manufacturing Co., Ltd., Nagaokakyo-shi (JP)

(72) Inventors: Kentaro FUJINAGA, Nagaokakyo-shi (JP); Goro TSUBOUCHI, Nagaokakyo-shi (JP); Takashi IWAMOTO, Nagaokakyo-shi (JP)

(21) Appl. No.: 19/416,415

(22) Filed: Dec. 11, 2025

Related U.S. Application Data
(63) Continuation of application No. PCT/JP2024/023956, filed on Jul. 2, 2024.

(30) Foreign Application Priority Data
Jul. 3, 2023 (JP) 2023-109597

(51) Int. Cl. H03H 9/02; H03H 9/17

(52) U.S. Cl. CPC H03H 9/02086; H03H 9/02015; H03H 9/17

(57) ABSTRACT

An acoustic wave device includes a piezoelectric layer including first and second main surfaces, an upper electrode on the first main surface, a lower electrode on the second main surface, and a support facing the second main surface of the piezoelectric layer. The piezoelectric layer includes an opening extending through the piezoelectric layer in a thickness direction in a region overlapping the lower electrode and not overlapping the upper electrode. The acoustic wave device further includes an overlapping electrode on the lower electrode in a region overlapping the opening and made of the same material as the upper electrode.

### CROSS REFERENCE TO RELATED APPLICATIONS

This application claims the benefit of priority to Japanese Patent Application No. 2023-109597 filed on Jul. 3, 2023 and is a Continuation Application of PCT Application No. PCT/JP2024/023956 filed on Jul. 2, 2024. The entire contents of each application are hereby incorporated herein by reference.

### BACKGROUND OF THE INVENTION

### 1. Field of the Invention

The present invention relates to acoustic wave devices.

### 2. Description of the Related Art

U.S. Patent Application Publication No. 2012/0205754 discloses a piezoelectric device including upper and lower electrodes having flat plate shapes on both sides of the piezoelectric layer.

In the piezoelectric device disclosed in U.S. Patent Application Publication No. 2012/0205754, when an unintended potential difference occurs between the upper electrode and the lower electrode, there is a possibility of damage to the electrodes and the piezoelectric layer.

### SUMMARY OF THE INVENTION

Example embodiments of the present invention provide acoustic wave devices in each of which damage to electrodes is reduced or prevented.

An acoustic wave device according to an example embodiment of the present invention includes a piezoelectric layer including a first main surface and a second main surface opposite to the first main surface, an upper electrode on the first main surface of the piezoelectric layer, a lower electrode on the second main surface of the piezoelectric layer, and a support facing the second main surface of the piezoelectric layer, the piezoelectric layer includes an opening extending through the piezoelectric layer in a thickness direction in a region that overlaps the lower electrode and does not overlap the upper electrode, and the acoustic wave device further includes an overlapping electrode on the lower electrode in a region that overlaps the opening and including a same material as the upper electrode.

In each of acoustic wave devices according to example embodiments of the present invention, damage to electrodes is reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of an acoustic wave device according to a first example embodiment of the present invention.

FIG. 2 is a cross-sectional view taken along line II-II′ in FIG. 1.

FIG. 3 is an explanatory diagram for explaining a method of manufacturing the acoustic wave device according to the first example embodiment of the present invention.

FIG. 4 is a cross-sectional view of an acoustic wave device according to a first modification of the first example embodiment of the present invention.

FIG. 5 is a cross-sectional view of an acoustic wave device according to a second modification of the first example embodiment of the present invention.

FIG. 6 is a cross-sectional view of an acoustic wave device according to a third modification of the first example embodiment of the present invention.

FIG. 7 is an explanatory diagram for explaining a method of manufacturing the acoustic wave device according to the third modification of the first example embodiment of the present invention.

FIG. 8 is a cross-sectional view of an acoustic wave device according to a second example embodiment of the present invention.

FIG. 9 is an explanatory diagram for explaining a method of manufacturing the acoustic wave device according to the second example embodiment of the present invention.

FIG. 10 is a cross-sectional view of an acoustic wave device according to a fourth modification of the second example embodiment of the present invention.

FIG. 11 is an explanatory diagram for explaining a method of manufacturing the acoustic wave device according to the fourth modification of the second example embodiment of the present invention.

FIG. 12 is a cross-sectional view of an acoustic wave device according to a fifth modification of the second example embodiment of the present invention.

FIG. 13 is a plan view of an acoustic wave device according to a third example embodiment of the present invention.

FIG. 14 is a cross-sectional view taken along line XIV-XIV′ in FIG. 13.

FIG. 15 is a cross-sectional view of an acoustic wave device according to a sixth modification of the third example embodiment of the present invention.

FIG. 16 is an explanatory diagram for explaining a method of manufacturing the acoustic wave device according to the sixth modification of the third example embodiment of the present invention.

FIG. 17 is a plan view of an acoustic wave device according to a seventh modification of the third example embodiment.

FIG. 18 is a cross-sectional view of an acoustic wave device according to a fourth example embodiment of the present invention.

FIG. 19 is a cross-sectional view of an acoustic wave device according to a fifth example embodiment of the present invention.

FIG. 20 is an explanatory diagram for explaining a method of manufacturing the acoustic wave device according to the fifth example embodiment of the present invention.

FIG. 21 is a cross-sectional view of an acoustic wave device according to a sixth example embodiment of the present invention.

FIG. 22 is an explanatory diagram for explaining a method of manufacturing an acoustic wave device according to an eighth modification of the first example embodiment of the present invention.

### DETAILED DESCRIPTION OF THE EXAMPLE EMBODIMENTS

Hereinafter, example embodiments of the present disclosure will be described in detail with reference to the drawings. The example embodiments are not intended to limit the present invention. Each example embodiment described in the present disclosure is for illustrating an example. Thus, for modifications and a second and subsequent example embodiments in which configurations can be partially replaced or combined between different example embodiments, the description of the elements common to those of a first example embodiment will be omitted, and only different points will be described. In particular, the same or similar operational advantages resulting from the same or similar configurations will not be referred to in each example embodiment.

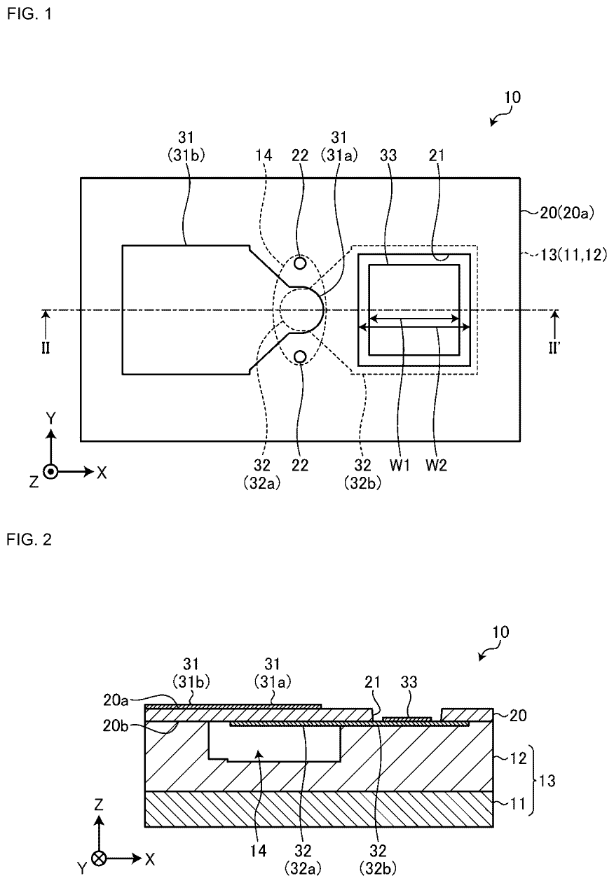

FIG. 1 is a plan view of an acoustic wave device according to a first example embodiment of the present invention. FIG. 2 is a cross-sectional view taken along line II-II′ in FIG. 1. The resonator defining and functioning as the acoustic wave device 10 according to the first example embodiment is a resonator that uses bulk acoustic waves, that is, a bulk-acoustic-wave (BAW) element.

As illustrated in FIGS. 1 and 2, the acoustic wave device 10 includes a support 13, a piezoelectric layer 20, an upper electrode 31, a lower electrode 32, and an overlapping electrode 33. As illustrated in FIG. 2, the lower electrode 32, the piezoelectric layer 20, the upper electrode 31 are laminated in this order on the support 13.

In the following description, the thickness direction of the piezoelectric layer 20 is regarded as the Z direction, a direction orthogonal or substantially orthogonal to the Z direction as the X direction, and the direction orthogonal or substantially orthogonal to the Z direction and the X direction as the Y direction. The X direction and the Y direction are parallel or substantially parallel to a surface (a first main surface 20a) of the piezoelectric layer 20. In the following description, plan views show the arrangement when viewed in the direction (the Z direction) perpendicular or substantially perpendicular to the first main surface 20a of the piezoelectric layer 20.

The support 13 faces a second main surface 20b of the piezoelectric layer 20. The support 13 includes a support substrate 11 and an insulating layer 12. The support substrate 11 is made of, for example, silicon (Si), quartz crystal, or the like. The insulating layer 12 is provided between the support substrate 11 and the piezoelectric layer 20. The insulating layer 12 is made of, for example, an insulating material such as silicon oxide. The support 13 may have a configuration that does not include the insulating layer 12, and in which the piezoelectric layer 20 is provided on the support substrate 11.

The support 13 (the insulating layer 12) includes a cavity portion 14 (a hollow portion) on the surface facing the second main surface 20b of the piezoelectric layer 20. The cavity portion 14 is provided to overlap the excitation region of the resonator including the piezoelectric layer 20, the upper electrode 31, and the lower electrode 32 overlapping one another in plan view. This configuration enables bulk acoustic waves to be reflected by the cavity portion 14.

The piezoelectric layer 20 has a flat plate shape including the first main surface 20a and the second main surface 20b opposite to the first main surface 20a. The piezoelectric layer 20 is a substrate made of, for example, single-crystal lithium niobate (LiNbO₃) or single-crystal lithium tantalate (LiTaO₃). The thickness of the piezoelectric layer 20 is not particularly limited and is, for example, preferably about 1 μm or less.

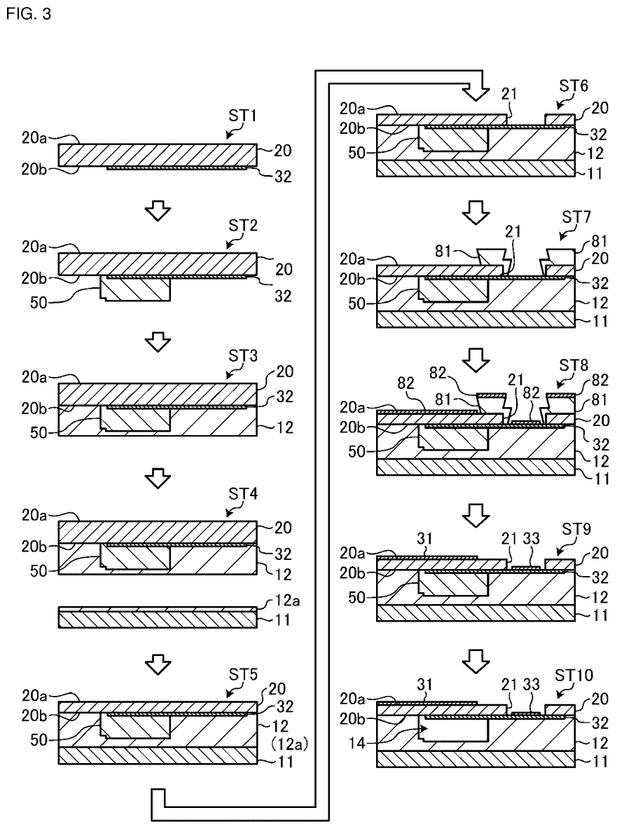

As illustrated in FIG. 1, the piezoelectric layer 20 includes etching openings 22 in a region that overlaps the cavity portion 14. The etching openings 22 are openings for etching when the cavity portion 14 of the insulating layer 12 is formed. Specifically, a sacrificial layer 50 (see FIG. 3) is provided in the region where the cavity portion 14 is to be formed. Then, after the piezoelectric layer 20 and the support 13 are joined together, the sacrificial layer 50 is removed through the etching openings 22, so that the cavity portion 14 is formed.

The upper electrode 31 is provided on the first main surface 20a of the piezoelectric layer 20. As illustrated in FIG. 1, the upper electrode 31 includes a main electrode portion 31a and an extension portion 31b coupled to the main electrode portion 31a and extending in the X direction. The main electrode portion 31a is provided in a region that overlaps the cavity portion 14 of the insulating layer 12 and is approximately circular. The extension portion 31b has a width larger than that of the main electrode portion 31a and is approximately rectangular. The extension portion 31b is electrically coupled to an external terminal (an input terminal or an output terminal) or a ground.

The lower electrode 32 is provided on the second main surface 20b of the piezoelectric layer 20 in a region at least partially overlapping the upper electrode 31. As illustrated in FIG. 1, the lower electrode 32 includes a main electrode portion 32a and an extension portion 32b coupled to the main electrode portion 32a and extending in the X direction. The main electrode portion 32a is provided in a region that overlaps the cavity portion 14 of the insulating layer 12 and is approximately circular. In other words, the main electrode portion 32a is provided in a region that overlaps the main electrode portion 31a of the upper electrode 31. An adhesion layer made of, for example, Ti, NiCr, or the like may be provided between the lower electrode 32 and the insulating layer 12.

The acoustic wave device 10 has a membrane structure in which the cavity portion 14 (the hollow portion) is provided on the second main surface 20b side of the piezoelectric layer 20. In a region that overlaps the cavity portion 14, the piezoelectric layer 20 is located between the main electrode portion 31a of the upper electrode 31 and the main electrode portion 32a of the lower electrode 32 in the Z direction. This configuration enables bulk acoustic waves to propagate between the main electrode portion 31a of the upper electrode 31 and the main electrode portion 32a of the lower electrode 32. In the following description, the region in which the upper electrode 31 and the lower electrode 32 overlap each other in plan view is sometimes referred to as the excitation region of the resonator.

The extension portion 32b of the lower electrode 32 has a width larger than that of the main electrode portion 32a and is approximately rectangular. The extension portion 32b extends in the X direction on the opposite side from the extension portion 31b of the upper electrode 31. In other words, the extension portion 32b is provided in a region that does not overlap the extension portion 31b of the upper electrode 31. The extension portion 32b is electrically coupled to an external terminal (an input terminal or an output terminal) or a ground.

The upper electrode 31 and the lower electrode 32 are made of a metal such as, for example, aluminum (Al), platinum (Pt), copper (Cu), tungsten (W), or molybdenum (Mo) or an alloy including at least one of these materials. The upper electrode 31 and the lower electrode 32 may be laminated films.

The piezoelectric layer 20 includes an opening 21 extending through it in the thickness direction. The opening 21 is provided in a region that overlaps the extension portion 32b of the lower electrode 32 and does not overlap the upper electrode 31. The extension portion 32b of the lower electrode 32 has an area larger than the opening 21 and covers the lower portion of the opening 21.

The overlapping electrode 33 is provided on the extension portion 32b of the lower electrode 32 in a region that overlaps the opening 21. The overlapping electrode 33 is in direct contact with the lower electrode 32. The overlapping electrode 33 is made of the same material as the upper electrode 31. Specifically, the overlapping electrode 33 is made of a metal such as, for example, Al, Pt, Cu, W, or Mo or an alloy including at least one of these materials. The overlapping electrode 33 is formed simultaneously in the same step as the upper electrode 31. The film formation step of the overlapping electrode 33 is described later with reference to FIG. 3.

The area of the overlapping electrode 33 is smaller than the area of the opening 21. In other words, the overlapping electrode 33 is provided in a region that overlaps the opening 21 so as to overlap a portion of the extension portion 32b of the lower electrode 32. The extension portion 32b of the lower electrode 32 includes, in the region that overlaps the opening 21, a portion covered with the overlapping electrode 33 and a portion not covered with the overlapping electrode 33. As illustrated in FIG. 1, both of the opening 21 and the overlapping electrode 33 are rectangular or substantially rectangular. The width W1 of the overlapping electrode 33 in the X direction is smaller than the width W2 of the opening 21 in the X direction. The width of the overlapping electrode 33 in the Y direction is also smaller than the width of the opening 21 the Y direction.

As described above, the acoustic wave device 10 of the present example embodiment has the opening 21 of the piezoelectric layer 20 and the overlapping electrode 33 in a region that overlaps the extension portion 32b of the lower electrode 32. Thus, the lower electrode 32 and the overlapping electrode 33 are exposed on the upper surface side (the first main surface 20a side), on which the upper electrode 31is located, through the opening 21 of the piezoelectric layer 20.

In a manufacturing step of the acoustic wave device 10, when the first main surface 20a side of the piezoelectric layer 20 is exposed to a specified atmosphere (for example, a plasma atmosphere), a certain potential sometimes occurs in the upper electrode 31. In the present example embodiment, the overlapping electrode 33 and the lower electrode 32 are also exposed to the atmosphere on the first main surface 20a side of the piezoelectric layer 20 through the opening 21 of the piezoelectric layer 20. Thus, the same or substantially the same potential is applied to the lower electrode 32 as to the upper electrode 31. Accordingly, the acoustic wave device 10 of the present example embodiment prevents the occurrence of an unintended potential difference between the upper electrode 31 and the lower electrode 32. This leads to a reduction of damage to the electrodes and the piezoelectric layer 20 caused by the potential difference between the upper electrode 31 and the lower electrode 32.

The plan-view shapes of the upper electrode 31 and the lower electrode 32 illustrated in FIG. 1 are mere examples and may be changed as appropriate. The plan-view shapes of the opening 21 of the piezoelectric layer 20 and the overlapping electrode 33 also are not limited to rectangular or substantially rectangular shapes and may be other shapes such as circular and polygonal shapes.

Next, an example or a method of manufacturing the acoustic wave device 10 of the present example embodiment will be described. FIG. 3 is an explanatory diagram for explaining the method of manufacturing the acoustic wave device according to the first example embodiment. As illustrated in FIG. 3, the piezoelectric layer 20 which is a single-crystal substrate made of, for example, LiNbO₃, LiTaO₃, or the like is prepared, and then the lower electrode 32 is formed on the second main surface 20b of the piezoelectric layer 20 (step ST1). The lower electrode 32 is formed by, for example, a vapor deposition lift-off method. Specifically, in step ST1, a resist pattern is formed on the second main surface 20b of the piezoelectric layer 20 by, for example, photolithography. A metal film is deposited, and then the resist is removed, so that the metal film is patterned to form the lower electrode 32. In step ST1, the lower electrode 32 is formed to include the main electrode portion 32a and the extension portion 32b (see FIG. 1) by the patterning.

Next, the sacrificial layer 50 is formed on the second main surface 20b of the piezoelectric layer 20 (step ST2). The sacrificial layer 50 is provided in the region where the cavity portion 14 of the support 13 (the insulating layer 12) is to be formed. In other words, the sacrificial layer 50 is provided to cover the main electrode portion 32a of the lower electrode 32. The sacrificial layer 50 is formed as a film by, for example, sputtering using a material such as zinc oxide (ZnO).

The insulating layer 12 is formed on the second main surface 20b of the piezoelectric layer 20 so as to cover the lower electrode 32 and the sacrificial layer 50 (step ST3). The insulating layer 12 is formed as a film by, for example, sputtering using a material such as silicon oxide. An adhesion layer made of, for example, Ti, NiCr, or the like may be provided between the layers of the lower electrode 32 and the insulating layer 12. The lower surface (the surface opposite to the piezoelectric layer 20) of the insulating layer 12 may be planarized as necessary by, for example, chemical mechanical polishing (CMP).

The support substrate 11 including an intermediate layer 12a on one surface is prepared, and then the intermediate layer 12a on the support substrate 11 is joined to the insulating layer 12 formed on the second main surface 20b of the piezoelectric layer 20. With this step, the support substrate 11 and the combination of the insulating layer 12 and the piezoelectric layer 20 are attached together (step ST4). More specifically, the intermediate layer 12a is formed of the same material as the insulating layer 12, for example, silicon oxide or the like. The support substrate 11 is joined to the insulating layer 12 by, for example, direct bonding, plasma-activated bonding, atom diffusion bonding, or the like. With this step, the intermediate layer 12a and the insulating layer 12 are integrated together. In the following description, when the intermediate layer 12a and the insulating layer 12 need not be distinguished, they are simply referred to as the insulating layer 12.

The first main surface 20a of the piezoelectric layer 20 is grounded and polished to reduce its thickness (step ST5). The first main surface 20a of the piezoelectric layer 20 is polished, for example, by mechanical polishing or CMP. The thickness of the piezoelectric layer 20 is set to be, for example, approximately 1 μm or less. Step ST5 is not limited to polishing. For example, the thickness of the piezoelectric layer 20 may be reduced by forming a damage layer in the piezoelectric layer 20 by ions plantation and stripping a layer on the upper surface of the formed damage layer.

The opening 21 is formed in the piezoelectric layer 20 at a position overlapping the lower electrode 32 and not overlapping the region where the upper electrode 31 is to be formed (step ST6). The opening 21 is formed by removing a portion of the piezoelectric layer 20 by reactive ion etching (RIE), for example.

Next, a pattern of a resist 81 is formed on the first main surface 20a of the piezoelectric layer 20 by, for example, photolithography (step ST7). In this step, the resist 81 is not formed in the region where the upper electrode 31 is to be formed and in the region that overlaps the opening 21 and in which the overlapping electrode 33 is to be formed. Then, a film of a metal layer 82 is formed on the entire or substantially the entire surface (step ST8). In step ST8, the metal layer 82 is formed both on the resist 81 and on the regions where the resist 81 is not formed. Simultaneously with the metal layer 82 defining and functioning as the upper electrode 31, the metal film 82 defining and functioning as the overlapping electrode 33 is formed on the lower electrode 32 in a region that overlaps the opening 21. Thereafter, the resist 81 is removed, and the metal film 82 in the portions not overlapping the resist 81 defines and functions as the upper electrode 31 and the overlapping electrode 33 (step ST9). As described above, in the present example embodiment, a vapor deposition lift-off method is used to form the upper electrode 31 on the first main surface 20a of the piezoelectric layer 20 and the overlapping electrode 33 on the lower electrode 32 in a region that overlaps the opening 21.

In step ST9, the upper electrode 31 is patterned to include the main electrode portion 31a and the extension portion 31b (see FIG. 1). The overlapping electrode 33 is formed simultaneously in the same step as the upper electrode 31. In this step, when the upper electrode 31 is formed, a portion of the lower electrode 32 is also exposed to the atmosphere on the first main surface 20a side of the piezoelectric layer 20 through the opening 21 of the piezoelectric layer 20. With this configuration, even when a certain potential occurs in the upper electrode 31 during the film formation of the upper electrode 31, the same or substantially the same potential occurs also in the lower electrode 32 as in the upper electrode 31 because the overlapping electrode 33 is formed on the lower electrode 32 through the opening 21 of the piezoelectric layer 20. Thus, in the manufacturing method of the present example embodiment, it is possible to reduce the potential difference between the upper electrode 31 and the lower electrode 32 that occurs during the film formation of the upper electrode 31.

As described above, since the thickness of the piezoelectric layer 20 is reduced to about 1 μm or less, for example, damage to the electrodes (the upper electrode 31 and the lower electrode 32) tends to occur in this structure when an unintended potential difference occurs between the upper electrode 31 and the lower electrode 32. In the present example embodiment, since the potential difference between the upper electrode 31 and the lower electrode 32 can be reduced, damage to the electrodes can be reduced even in the configuration in which the thickness of the piezoelectric layer 20 is reduced to about 1 μm or less, for example.

Next, the sacrificial layer 50 is removed, so that the cavity portion 14 is formed in the insulating layer 12 (step ST10). With this step, the membrane structure of the piezoelectric layer 20 is formed. The sacrificial layer 50 is removed by, for example, wet etching. In this step, an etchant for dissolving the sacrificial layer 50 is introduced through the etching openings 22 (see FIG. 1).

Through these steps described above, the acoustic wave device 10 of the present example embodiment is manufactured. The steps illustrated in FIG. 3 are merely a schematic illustration and can be changed as appropriate.

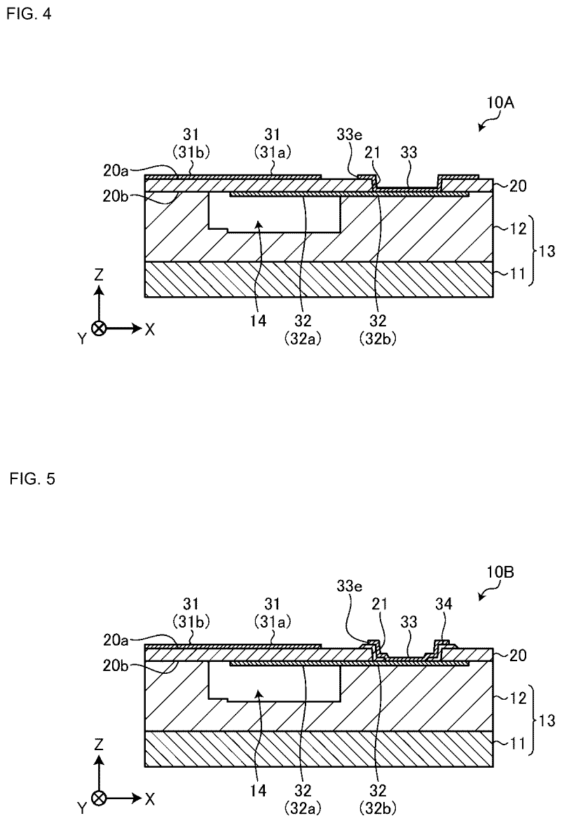

FIG. 4 is a cross-sectional view of an acoustic wave device according to a first modification of the first example embodiment. As illustrated in FIG. 4, the acoustic wave device 10A according to the first modification is different from the first example embodiment described above in that the area of the overlapping electrode 33 is larger than the area of the opening 21 of the piezoelectric layer 20.

The overlapping electrode 33 is provided on the extension portion 32b of the lower electrode 32 in a region that overlaps the opening 21 of the piezoelectric layer 20. The overlapping electrode 33 is provided to extend along the inner wall of the opening 21 of the piezoelectric layer 20 and onto the first main surface 20a of the piezoelectric layer 20. The outer edge 33e of the overlapping electrode 33 is on the first main surface 20a of the piezoelectric layer 20 and away from the upper electrode 31.

Since the overlapping electrode 33 has a large area in the first modification, it is possible to protect the inner wall of the opening 21 of the piezoelectric layer 20. The overlapping electrode 33 prevents separation between the piezoelectric layer 20 and the lower electrode 32 in the vicinity of the opening 21 of the piezoelectric layer 20.

The first modification can also be formed through the same or similar steps as the above-described manufacturing method illustrated in FIG. 3. Specifically, in the vapor deposition lift-off method in steps ST7 to ST9 in FIG. 3, when the resist pattern is formed by, for example, photolithography, the resist is not formed in the region that overlaps the opening 21 and in the vicinity of the opening 21 on the first main surface 20a of the piezoelectric layer 20. With this step, the metal film is formed in a region that overlaps the opening 21 of the piezoelectric layer 20 so as to extend on the extension portion 32b of the lower electrode 32, along the inner wall of the opening 21 of the piezoelectric layer 20, and onto the first main surface 20a of the piezoelectric layer 20. Thus, the overlapping electrode 33 is formed to have an area larger than the area of the opening 21 of the piezoelectric layer 20.

FIG. 5 is a cross-sectional view of an acoustic wave device according to a second modification of the first example embodiment. As illustrated in FIG. 5, the acoustic wave device 10B according to the second modification is different from the first modification described above in that it includes an interlayer insulating layer 34 covering the outer edge of the opening 21 of the piezoelectric layer 20.

The interlayer insulating layer 34 is provided between the inner wall of the opening 21 and the overlapping electrode 33 and between the first main surface 20a of the piezoelectric layer 20 and the overlapping electrode 33. The interlayer insulating layer 34 is also provided between the overlapping electrode 33 and the outer edge of the lower electrode 32 in the region that overlaps the opening 21 of the piezoelectric layer 20. In other words, the interlayer insulating layer 34 includes an opening in a region that overlaps the opening 21 of the piezoelectric layer 20, and the lower electrode 32 and the overlapping electrode 33 are in direct contact with each other through the opening of the interlayer insulating layer 34.

Although illustration of the state is omitted, the interlayer insulating layer 34 is formed along the inner wall of the opening 21 in plan view. The interlayer insulating layer 34 may be continuously formed in a frame shape along the inner wall of the opening 21 or may be provided along a portion of the inner wall of the opening 21.

Since the interlayer insulating layer 34 is provided between the outer edge 33e of the overlapping electrode 33 and the first main surface 20a of the piezoelectric layer 20 in the second modification, the distance between the outer edge 33e of the overlapping electrode 33 and the upper electrode 31 is longer than in a configuration without the interlayer insulating layer 34. This configuration reduces a stray capacitance between the upper electrode 31 and the overlapping electrode 33, more specifically, a stray capacitance between the upper electrode 31 and the lower electrode 32 with the overlapping electrode 33 interposed therebetween.

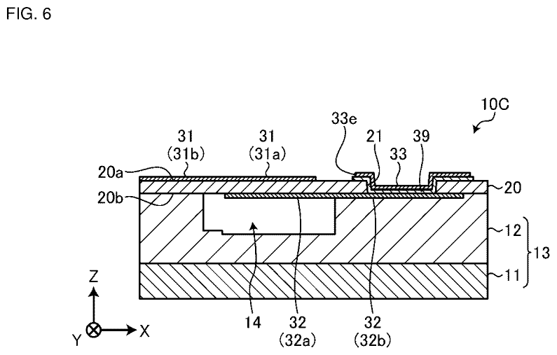

FIG. 6 is a cross-sectional view of an acoustic wave device according to a third modification of the first example embodiment. As illustrated in FIG. 6, the acoustic wave device 10C according to the third modification is different from the first modification described above in that it includes an intermediate conductive layer 39 between the lower electrode 32 and the overlapping electrode 33 in a region that overlaps the opening 21 of the piezoelectric layer 20.

The intermediate conductive layer 39 covers the entire or substantially the entire region of the lower electrode 32 in the region that overlaps the opening 21. The intermediate conductive layer 39 is also provided between the inner wall of the opening 21 and the overlapping electrode 33 and between the first main surface 20a of the piezoelectric layer 20 and the overlapping electrode 33.

The intermediate conductive layer 39 is made of a material (a metal material or an alloy) different from that of the upper electrode 31 and the overlapping electrode 33. In the case in which the overlapping electrode 33 is directly laminated on the lower electrode 32, the surface of the lower electrode 32 becomes alloyed in some cases, depending on the combination of the material of the lower electrode 32 and the material of the upper electrode 31 and the overlapping electrode 33. In the third modification, the intermediate conductive layer 39 makes it possible to prevent alloying between the lower electrode 32 and the overlapping electrode 33. In other words, the intermediate conductive layer 39 is provided as a barrier layer between the lower electrode 32 and the overlapping electrode 33.

In addition, the intermediate conductive layer 39 makes the total thickness of the lower electrode 32, the intermediate conductive layer 39, and the overlapping electrode 33 larger than in a configuration without the intermediate conductive layer 39. This configuration reduces the wiring resistance of the lower electrode 32.

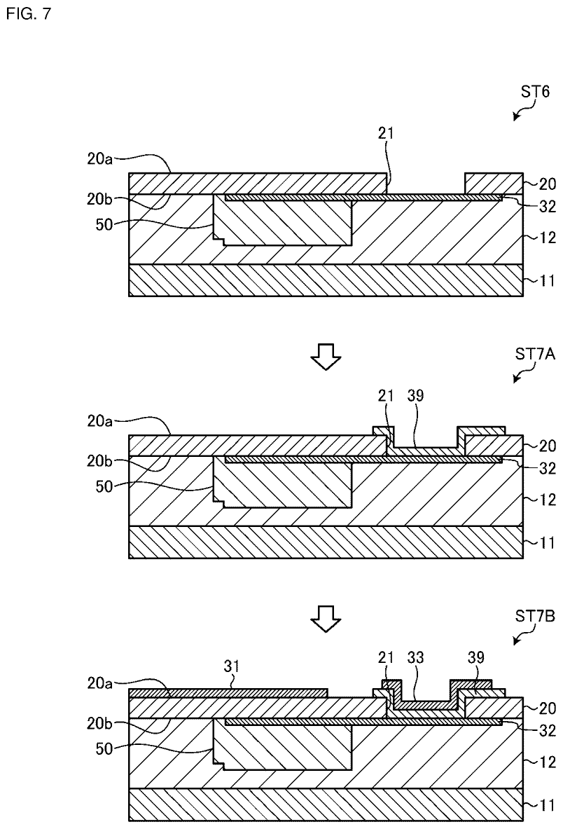

FIG. 7 is an explanatory diagram for explaining an example of a method of manufacturing the acoustic wave device according to the third modification of the first example embodiment. The method of manufacturing the acoustic wave device 10C according to the third modification is different from the manufacturing method illustrated in FIG. 3 in the process of forming the upper electrode 31 in steps ST7 to ST9. Steps ST1 to ST6 and ST10 in FIG. 3 are the same or similar in the method of manufacturing the acoustic wave device 10C according to the third modification.

As illustrated in FIG. 7, after the opening 21 of the piezoelectric layer 20 is formed in step ST6, the intermediate conductive layer 39 is formed on the lower electrode 32 in a region that overlaps the opening 21 (step ST7A) before the upper electrode 31 and the overlapping electrode 33 are formed. The intermediate conductive layer 39 is formed by, for example, a vapor deposition lift-off method.

Next, the upper electrode 31 is formed on the first main surface 20a of the piezoelectric layer 20, and the overlapping electrode 33 is formed on the intermediate conductive layer 39 in a region that overlaps the opening 21 (step ST7B). The upper electrode 31 and the overlapping electrode 33 are formed by, for example, a vapor deposition lift-off method in the same or a similar manner as in steps ST7 to ST9 (see FIG. 3) described above.

Even in such a configuration that alloying occurs when the overlapping electrode 33 is directly laminated on the lower electrode 32, the overlapping electrode 33 is not in direct contact with the lower electrode 32 because the intermediate conductive layer 39 is provided in advance in the present modification. Thus, alloying of the surface of the lower electrode 32 is prevented, and the overlapping electrode 33 and the lower electrode 32 maintain favorable conductivity with the intermediate conductive layer 39 interposed therebetween. The acoustic wave device 10C in the present modification reduces the potential difference between the upper electrode 31 and the lower electrode 32 that occurs during the film formation of the upper electrode 31.

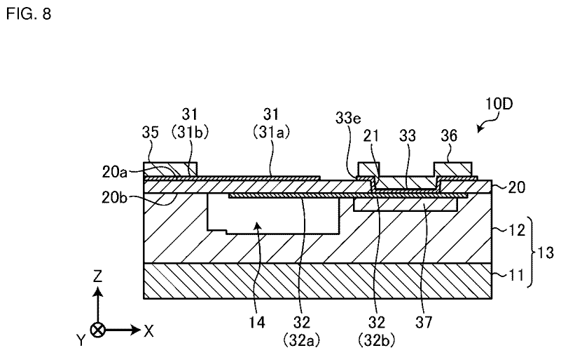

FIG. 8 is a cross-sectional view of an acoustic wave device according to the second example embodiment. As illustrated in FIG. 8, the acoustic wave device 10D according to the second example embodiment is different from the first modification of the first example embodiment (see FIG. 4) in that it includes front surface electrodes 35 and 36 and a back surface electrode 37.

The front surface electrode 35 is laminated on the extension portion 31b of the upper electrode 31. The front surface electrode 36 is laminated on the overlapping electrode 33. In the present example embodiment, the overlapping electrode 33 has an area larger than the area of the opening 21. The front surface electrode 36 also has an area larger than the area of the opening 21. The front surface electrode 36 is provided on the overlapping electrode 33 in a region that overlaps the opening 21 and is also provided on the overlapping electrode 33 so as to cover the inner wall of the opening 21 and a portion of the first main surface 20a of the piezoelectric layer 20 in the vicinity of the opening 21.

The back surface electrode 37 is laminated between the extension portion 32b of the lower electrode 32 and the insulating layer 12. The front surface electrodes 35 and 36 and the back surface electrode 37 are not provided on the main electrode portion 31a of the upper electrode 31 and the main electrode portion 32a of the lower electrode 32 which define the membrane structure.

The front surface electrode 35 reduces the wiring resistance of the main electrode portion 31a of the upper electrode 31. The back surface electrode 37 reduces the wiring resistance of the main electrode portion 32a of the lower electrode 32. In addition, the front surface electrode 36 reduces the wiring resistance in the portion where the extension portion 32b of the lower electrode 32 and the overlapping electrode 33 are laminated.

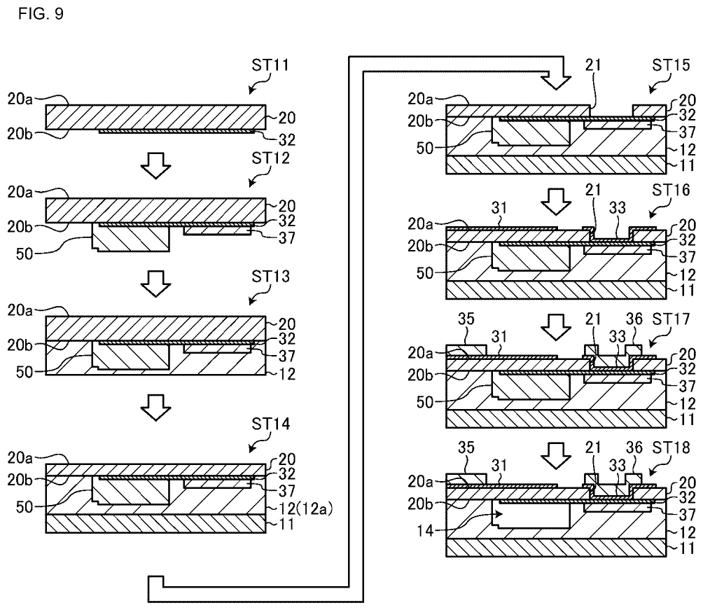

FIG. 9 is an explanatory diagram for explaining an example of a method of manufacturing the acoustic wave device according to the second example embodiment. In the description of the manufacturing method illustrated in FIG. 9, the description of portions overlapping the above-described manufacturing method illustrated in FIG. 3 is omitted. As illustrated in FIG. 9, first, the lower electrode 32 is formed on the second main surface 20b of the piezoelectric layer 20 (step ST11).

Next, the sacrificial layer 50 and the back surface electrode 37 are formed on the second main surface 20b of the piezoelectric layer 20 (step ST12). The back surface electrode 37 is provided to cover the extension portion 32b of the lower electrode 32 in a region where the opening 21 of the piezoelectric layer 20 is to be formed. The back surface electrode 37 is formed by, for example, a vapor deposition lift-off method, similarly to the lower electrode 32. Thereafter, the sacrificial layer 50 is provided to cover the main electrode portion 32a of the lower electrode 32. The sacrificial layer 50 is formed as a film by, for example, sputtering using a material such as zinc oxide (ZnO).

The insulating layer 12 is formed on the second main surface 20b of the piezoelectric layer 20 so as to cover the lower electrode 32, the back surface electrode 37, and the sacrificial layer 50 (step ST13). The insulating layer 12 is formed as a film by, for example, sputtering using a material such as silicon oxide. An adhesion layer including, for example, Ti, NiCr, or the like may be provided between the layers of the lower electrode 32 and the insulating layer 12 and between the layers of the back surface electrode 37 and the insulating layer 12. The lower surface (the surface opposite to the piezoelectric layer 20) of the insulating layer 12 may be planarized as necessary by CMP, for example.

The support substrate 11 including the intermediate layer 12a on one surface is prepared, and then, the intermediate layer 12a on the support substrate 11 is joined to the insulating layer 12 formed on the second main surface 20b of the piezoelectric layer 20. With this step, the support substrate 11 and the combination of the insulating layer 12 and the piezoelectric layer 20 are attached together (step ST14). As in step ST5 (see FIG. 3), the first main surface 20a of the piezoelectric layer 20 is grounded and polished to reduce its thickness.

The opening 21 is formed in the piezoelectric layer 20 in a region that overlaps the lower electrode 32 and the back surface electrode 37 and does not overlap the upper electrode 31 (step ST15). The opening 21 is formed by removing a portion of the piezoelectric layer 20 by reactive ion etching (RIE), for example.

The upper electrode 31 is formed on the first main surface 20a of the piezoelectric layer 20, and the overlapping electrode 33 is formed on the lower electrode 32 in a region that overlaps the opening 21 (step ST16). The upper electrode 31 and the overlapping electrode 33 are formed by, for example, a vapor deposition lift-off method. In the present example embodiment, the overlapping electrode 33 is formed to have an area larger than the area of the opening 21 of the piezoelectric layer 20. Also in the present example embodiment, the overlapping electrode 33 is formed simultaneously in the same step as the upper electrode 31. This configuration makes it possible to reduce the potential difference between the upper electrode 31 and the lower electrode 32 that occurs during the film formation of the upper electrode 31.

Next, the front surface electrode 35 is formed on the extension portion 31b of the upper electrode 31, and the front surface electrode 36 is formed on the overlapping electrode 33 (step ST17). The front surface electrodes 35 and 36 are formed by, for example, a vapor deposition lift-off method.

In the present example embodiment, the front surface electrode 36 that overlaps the overlapping electrode 33 is formed simultaneously in the same step as the front surface electrode 35 that overlaps the upper electrode 31. In this step, when the front surface electrode 35 is formed, the overlapping electrode 33 is also exposed to the atmosphere on the first main surface 20a side of the piezoelectric layer 20. Thus, even when a certain potential occurs in the front surface electrode 35 and the upper electrode 31 during the film formation of the front surface electrode 35, the same or substantially the same potential occurs also in the lower electrode 32 as in the upper electrode 31 because the front surface electrode 36 is formed on the overlapping electrode 33. Thus, in the manufacturing method of the present example embodiment, it is possible to reduce the potential difference between the upper electrode 31 and the lower electrode 32 that occurs during the film formation of the front surface electrode 35.

Next, the sacrificial layer 50 is removed, so that the cavity portion 14 is formed in the insulating layer 12 (step ST18). This step forms the membrane structure of the piezoelectric layer 20.

The acoustic wave device 10D of the second example embodiment is manufactured through these steps described above. The steps illustrated in FIG. 9 are merely a schematic illustration and can be changed as appropriate.

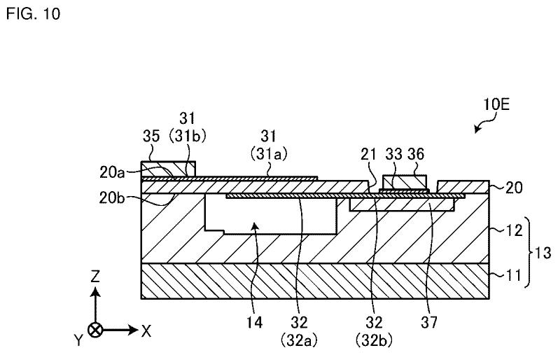

FIG. 10 is a cross-sectional view of an acoustic wave device according to a fourth modification of the second example embodiment. As illustrated in FIG. 10, the acoustic wave device 10E according to the fourth modification is different from the acoustic wave device 10D of the second example embodiment described above in that the areas of the overlapping electrode 33 and the front surface electrode 36 are smaller than the area of the opening 21.

The overlapping electrode 33 and the front surface electrode 36 are provided to overlap a portion of the extension portion 32b of the lower electrode 32 in the region that overlaps the opening 21. In other words, the extension portion 32b of the lower electrode 32 includes, in the region that overlaps the opening 21, a portion covered with the overlapping electrode 33 and the front surface electrode 36 and a portion not covered with the overlapping electrode 33 and the front surface electrode 36.

Since the areas occupied by the overlapping electrode 33 and the front surface electrode 36 in the fourth modification are smaller than those in the second example embodiment described above, the acoustic wave device 10E can be downsized. In addition, the distance between the combination of the upper electrode 31 and the front surface electrode 35 and the combination of the overlapping electrode 33 and the front surface electrode 36 is larger than in the second example embodiment described above. This configuration reduces a stray capacitance between the combination of the upper electrode 31 and the front surface electrode 35 and the combination of the overlapping electrode 33 and the front surface electrode 36.

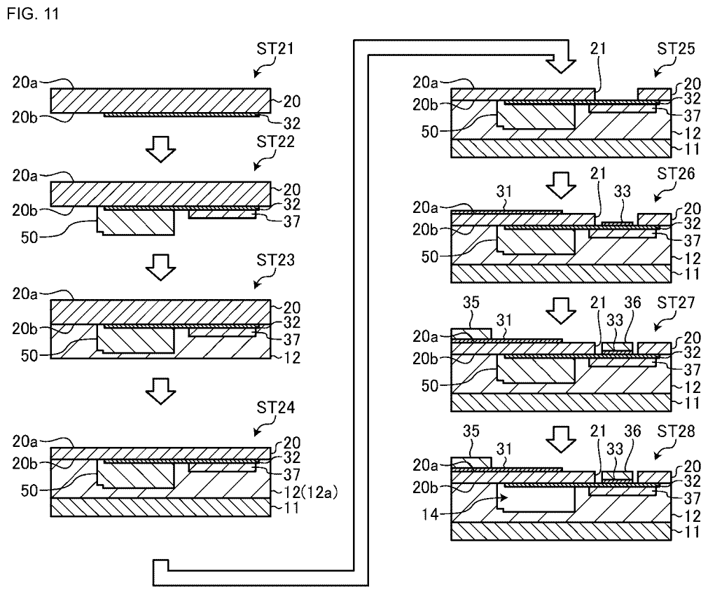

FIG. 11 is an explanatory diagram for explaining an example of a method of manufacturing the acoustic wave device according to the fourth modification of the second example embodiment. In the method of manufacturing the acoustic wave device 10E according to the fourth modification illustrated in FIG. 11, steps ST21 to ST25 are the same as or similar to steps ST11 to ST15 described above with reference to FIG. 9, and thus repetitive description is omitted.

As illustrated in FIG. 11, after the opening 21 is formed in the piezoelectric layer 20, the upper electrode 31 is formed on the first main surface 20a of the piezoelectric layer 20, and the overlapping electrode 33 is formed on the lower electrode 32 in a region that overlaps the opening 21 (step ST26). The upper electrode 31 and the overlapping electrode 33 are formed by, for example, a vapor deposition lift-off method. In the fourth modification, the overlapping electrode 33 is formed to have an area smaller than the area of the opening 21 of the piezoelectric layer 20.

Next, the front surface electrode 35 is formed on the extension portion 31b of the upper electrode 31, and the front surface electrode 36 is formed on the overlapping electrode 33 (step ST27). The front surface electrode 36 is formed to have an area smaller than the area of the opening 21 of the piezoelectric layer 20. The front surface electrodes 35 and 36 are formed by, for example, a vapor deposition lift-off method.

Next, the sacrificial layer 50 is removed, so that the cavity portion 14 is formed in the insulating layer 12 (step ST28). This step forms the membrane structure of the piezoelectric layer 20.

The acoustic wave device 10E of the fourth modification is manufactured through these steps described above. The steps illustrated in FIG. 11 are merely a schematic illustration and can be changed as appropriate.

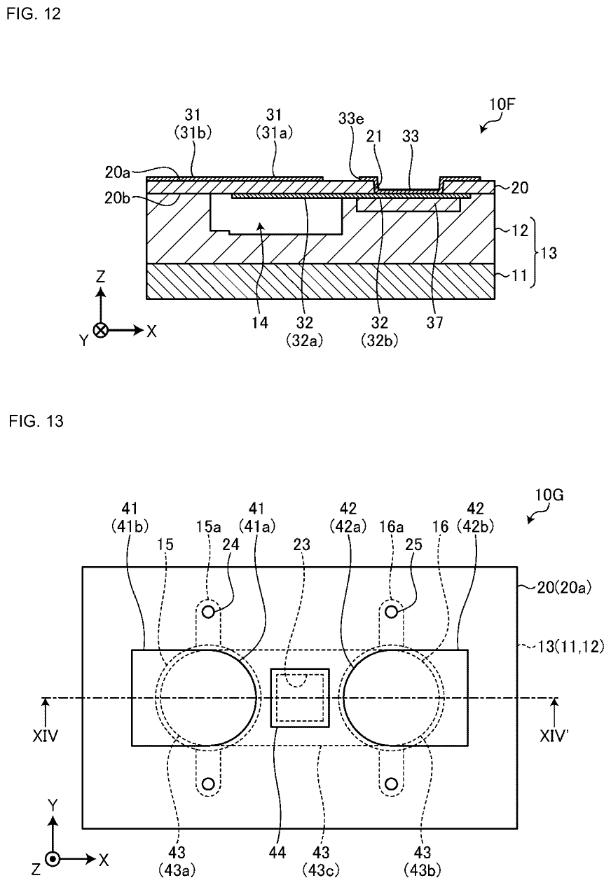

FIG. 12 is a cross-sectional view of an acoustic wave device according to a fifth modification of the second example embodiment. As illustrated in FIG. 12, the acoustic wave device 10F according to the fifth modification is different from the acoustic wave device 10D according to the second example embodiment described above in that it includes the back surface electrode 37 and does not include the front surface electrodes 35 and 36.

Also in the fifth modification, the back surface electrode 37 reduces the wiring resistance of the lower electrode 32.

The layouts, the areas, and other conditions of the front surface electrodes 35 and 36 and the back surface electrode 37 illustrated in the second example embodiment, the fourth modification, and the fifth modification can be changed as appropriate according to the characteristics required for the acoustic wave device 10F. The configuration example is not limited to the fifth modification. A configuration in which the front surface electrodes 35 and 36 are provided and the back surface electrode 37 is not provided is also possible.

The front surface electrodes 35 and 36 and the back surface electrode 37 illustrated in the second example embodiment, the fourth modification, and the fifth modification can be combined with the second or third modification of the first example embodiment described above.

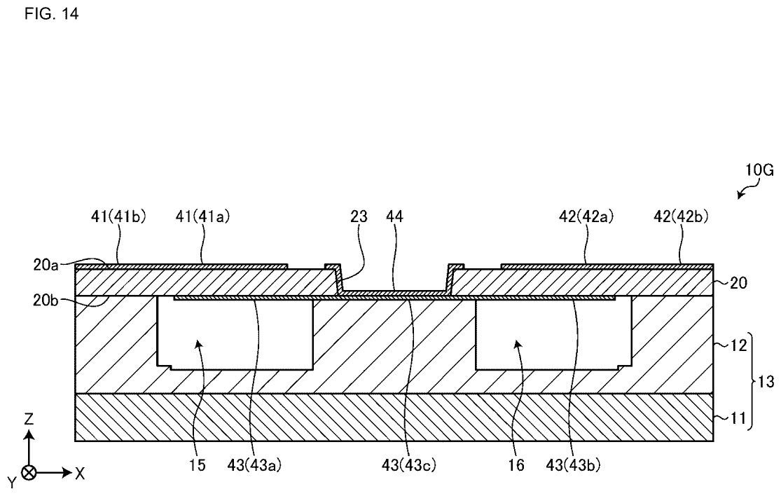

FIG. 13 is a plan view of an acoustic wave device according to a third example embodiment of the present invention. FIG. 14 is a cross-sectional view taken along line XIV-XIV′ in FIG. 13. As illustrated in FIGS. 13 and 14, the acoustic wave device 10G according to the third example embodiment is different from the first and second example embodiments described above in that it includes two resonators.

As illustrated in FIGS. 13 and 14, the acoustic wave device 10G according to the third example embodiment includes a support 13, a piezoelectric layer 20, a first upper electrode 41, a second upper electrode 42, a lower electrode 43, and an overlapping electrode 44.

The support 13 (an insulating layer 12) includes a first cavity portion 15 (a hollow portion) and a second cavity portion 16 (a hollow portion) on the surface facing the second main surface 20b of the piezoelectric layer 20. The first cavity portion 15 and the second cavity portion 16 are spaced from each other in the X direction. The first cavity portion 15 overlaps the excitation region of the resonator including the piezoelectric layer 20, the first upper electrode 41, and the lower electrode 43 overlapping one another. The second cavity portion 16 overlaps the excitation region of the resonator including the piezoelectric layer 20, the second upper electrode 42, and the lower electrode 43 overlapping one another.

As illustrated in FIG. 13, the piezoelectric layer 20 includes etching openings 24 in a region that overlaps the first cavity portion 15. The piezoelectric layer 20 includes etching openings 25 in a region that overlaps the second cavity portion 16. The etching openings 24 and 25 are openings for etching when the first cavity portion 15 and the second cavity portion 16 of the insulating layer 12 are formed.

The first upper electrode 41 and the second upper electrode 42 are provided on the first main surface 20a of the piezoelectric layer 20. The first upper electrode 41 and the second upper electrode 42 are spaced from each other in the X direction. As illustrated in FIG. 13, the first upper electrode 41 includes a first main electrode portion 41a and a first extension portion 41b coupled to the first main electrode portion 41a and extending in the X direction. The first main electrode portion 41a is provided in a region that overlaps the first cavity portion 15 of the insulating layer 12 and is approximately circular. The first extension portion 41b has a width equal or approximately equal to the diameter of the first main electrode portion 41a.

The second upper electrode 42 includes a second main electrode portion 42a and a second extension portion 42b coupled to the second main electrode portion 42a and extending in the X direction. The second main electrode portion 42a is provided in a region that overlaps the second cavity portion 16 of the insulating layer 12 and is approximately circular. The second extension portion 42b has a width equal or approximately equal to the diameter of the second main electrode portion 42a and extends on the opposite side from the first extension portion 41b.

The first extension portion 41b and the second extension portion 42b are electrically coupled to external terminals (input terminals or output terminals) or a ground.

The lower electrode 43 is provided on the second main surface 20b of the piezoelectric layer 20 in a region where the lower electrode 43 at least partially overlaps both of the first upper electrode 41 and the second upper electrode 42. The lower electrode 43 extends in the X direction and includes a first main electrode portion 43a located on one end side in the X direction, a second main electrode portion 43b located on the other end side in the X direction, and a coupling portion 43c coupling the first main electrode portion 43a and the second main electrode portion 43b.

The first main electrode portion 43a is provided in a region that overlaps the first cavity portion 15 of the insulating layer 12 and is approximately circular. In other words, the first main electrode portion 43a is provided in a region that overlaps the first main electrode portion 41a of the first upper electrode 41. The second main electrode portion 43b is provided in a region that overlaps the second cavity portion 16 of the insulating layer 12 and is approximately circular. In other words, the second main electrode portion 43b is provided in a region that overlaps the second main electrode portion 42a of the second upper electrode 42.

The acoustic wave device 10 includes membrane structures on the second main surface 20b side of the piezoelectric layer 20 in the portions where the first cavity portion 15 and the second cavity portion 16 are provided, respectively. In a region that overlaps the first cavity portion 15, the piezoelectric layer 20 is located between the first main electrode portion 41a of the first upper electrode 41 and the first main electrode portion 43a of the lower electrode 43 in the Z direction. This configuration enables bulk acoustic waves to propagate between the first main electrode portion 41a of the first upper electrode 41 and the first main electrode portion 43a of the lower electrode 43.

In a region that overlaps the second cavity portion 16, the piezoelectric layer 20 is located between the second main electrode portion 42a of the second upper electrode 42 and the second main electrode portion 43b of the lower electrode 43 in the Z direction. This configuration enables bulk acoustic waves to propagate between the second main electrode portion 42a of the second upper electrode 42 and the second main electrode portion 43b of the lower electrode 43.

In the following description, the region in which the first upper electrode 41 and the lower electrode 43 overlap each other in plan view and the region in which the second upper electrode 42 and the lower electrode 43 overlap each other in plan view may be referred to as the excitation regions of the resonators.

The coupling portion 43c of the lower electrode 43 has a width equal or approximately equal to the diameters of the first main electrode portion 43a and the second main electrode portion 43b and extends in the X direction. The coupling portion 43c is positioned between the first upper electrode 41 and the second upper electrode 42 in plan view. In other words, the coupling portion 43c is provided in a region that does not overlap either the first upper electrode 41 or the second upper electrode 42.

The piezoelectric layer 20 includes an opening 23 provided in a region that overlaps the coupling portion 43c of the lower electrode 43 and does not overlap the first upper electrode 41 and the second upper electrode 42. The coupling portion 43c of the lower electrode 43 has an area larger than the opening 23 and covers the lower portion of the opening 23.

The overlapping electrode 44 is provided on the coupling portion 43c of the lower electrode 43 in a region that overlaps the opening 23. The overlapping electrode 44 is in direct contact with the lower electrode 43. The overlapping electrode 44 is made of the same material as the first upper electrode 41 and the second upper electrode 42. Specifically, the overlapping electrode 44 is made of a metal such as, for example, Al, Pt, Cu, W, or Mo or an alloy including at least one of these materials.

The overlapping electrode 44 has an area larger than the area of the opening 23. The overlapping electrode 44 is provided on the coupling portion 43c of the lower electrode 43 in the region that overlaps the opening 23 of the piezoelectric layer 20 and extends along the inner wall of the opening 21 of the piezoelectric layer 20 and onto the first main surface 20a of the piezoelectric layer 20. The outer edge of the overlapping electrode 44 is provided on the first main surface 20a of the piezoelectric layer 20 and away from the first upper electrode 41 and the second upper electrode 42.

As described above, in the acoustic wave device 10G of the present example embodiment, the opening 23 of the piezoelectric layer 20 and the overlapping electrode 44 are provided in regions overlapping the coupling portion 43c of the lower electrode 43. In this configuration, when the first upper electrode 41 and the second upper electrode 42 are provided, the lower electrode 43 receives the same or substantially the same potential as the first upper electrode 41 and the second upper electrode 42 via the overlapping electrode 44. Thus, the acoustic wave device 10G of the present example embodiment reduces or prevents the occurrence of an unintended potential difference between the first and second upper electrodes 41 and 42 and the lower electrode 43. This reduces or prevents damage to the electrodes and the piezoelectric layer 20 caused by the potential difference between the first and second upper electrodes 41 and 42 and the lower electrode 43.

In the example embodiment illustrated in FIG. 14, the thickness of the piezoelectric layer 20 is constant across the two resonators. However, the present invention is not limited to this example embodiment, and the thickness of the piezoelectric layer 20 may be different between the excitation region where the first main electrode portion 41a of the first upper electrode 41 overlaps the first main electrode portion 43a of the lower electrode 43 and the excitation region where the second main electrode portion 42a of the second upper electrode 42 overlaps the second main electrode portion 43b of the lower electrode 43. In this case, the frequency characteristics can be appropriately adjusted for each of the two resonators.

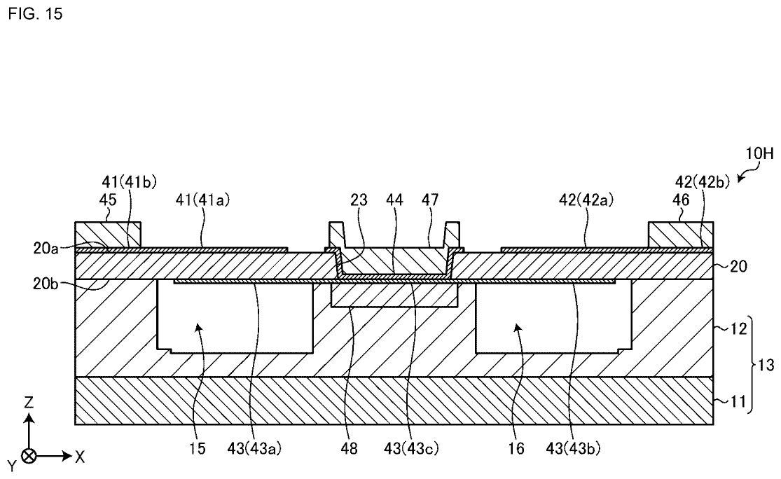

FIG. 15 is a cross-sectional view of an acoustic wave device according to a sixth modification of the third example embodiment. As illustrated in FIG. 15, the acoustic wave device 10H according to the sixth example embodiment is different from the third example embodiment in that it includes front surface electrodes 45, 46, and 47 and a back surface electrode 48.

The front surface electrode 45 is laminated on the first extension portion 41b of the first upper electrode 41. The front surface electrode 46 is laminated on the second extension portion 42b of the second upper electrode 42. The front surface electrode 47 is laminated on the overlapping electrode 44. In the present example embodiment, the overlapping electrode 44 has an area larger than the area of the opening 23. The front surface electrode 47 has an area larger than the area of the opening 23. The front surface electrode 47 is provided on the overlapping electrode 44 in a region that overlaps the opening 23 and is also provided on the overlapping electrode 44 so as to cover the inner wall of the opening 23 and a portion of the first main surface 20a of the piezoelectric layer 20 in the vicinity of the opening 23.

The back surface electrode 48 is laminated between the coupling portion 43c of the lower electrode 43 and the insulating layer 12. The front surface electrodes 45, 46, and 47 and the back surface electrode 48 are not provided on the first main electrode portion 41a of the first upper electrode 41, the second main electrode portion 42a of the second upper electrode 42, the first and second main electrode portions 43a and 43b of the lower electrode 43, which define the membrane structures.

Since the present modification includes the front surface electrodes 45 and 46, the wiring resistances of the first upper electrode 41 and the second upper electrode 42 can be reduced. In addition, the back surface electrode 48 reduces the wiring resistance of the lower electrode 43. Furthermore, the front surface electrode 47 reduces the wiring resistance of the portion where the coupling portion 43c of the lower electrode 43 and the overlapping electrode 44 are laminated.

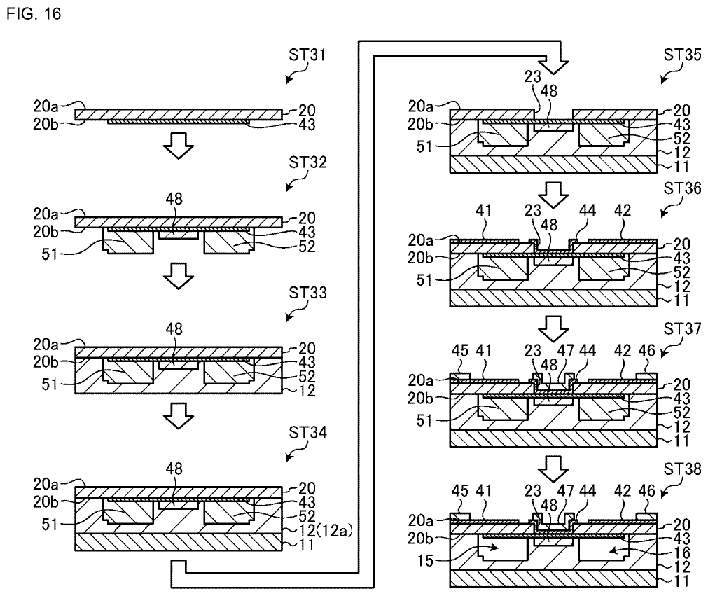

FIG. 16 is an explanatory diagram for explaining an example of a method of manufacturing the acoustic wave device according to the sixth modification of the third example embodiment. In the description of the manufacturing method illustrated in FIG. 16, the description of portions overlapping the above-described manufacturing methods is omitted. As illustrated in FIG. 16, first, the lower electrode 43 is formed on the second main surface 20b of the piezoelectric layer 20 (step ST31).

Next, the sacrificial layers 51 and 52 and the back surface electrode 48 are formed on the second main surface 20b of the piezoelectric layer 20 (step ST32). The back surface electrode 48 is provided to cover the coupling portion 43c of the lower electrode 43 in the region where the opening 23 of the piezoelectric layer 20 is to be formed. The back surface electrode 48 is formed by, for example, a vapor deposition lift-off method, similarly to the lower electrode 43. Thereafter, the sacrificial layer 51 is provided to cover the first main electrode portion 43a of the lower electrode 43. The sacrificial layer 51 is formed in the region where the first cavity portion 15 of the insulating layer 12 is to be formed. The sacrificial layer 52 is provided to cover the second main electrode portion 43b of the lower electrode 43. The sacrificial layer 52 is formed in the region where the second cavity portion 16 of the insulating layer 12 is to be formed. The sacrificial layers 51 and 52 are formed as films by, for example, sputtering using a material such as zinc oxide (ZnO).

The insulating layer 12 is formed on the second main surface 20b of the piezoelectric layer 20 so as to cover the lower electrode 43, the back surface electrode 48, and the sacrificial layers 51 and 52 (step ST33). The insulating layer 12 is formed as a film by, for example, sputtering using a material such as silicon oxide. An adhesion layer made of, for example, Ti, NiCr, or the like may be provided between the layers of the lower electrode 43 and the insulating layer 12 and between the layers of the back surface electrode 48 and the insulating layer 12. The lower surface (the surface opposite to the piezoelectric layer 20) of the insulating layer 12 may be planarized as necessary by CMP, for example.

The support substrate 11 including the intermediate layer 12a on one surface is prepared, and the support substrate 11 and the combination of the insulating layer 12 and the piezoelectric layer 20 are attached together (step ST34). As in step ST5 (see FIG. 3), the first main surface 20a of the piezoelectric layer 20 is grounded and polished to reduce its thickness.

The opening 23 is formed in the piezoelectric layer 20 in a region that overlaps the lower electrode 43 and the back surface electrode 48 and does not overlap the first upper electrode 41 and the second upper electrode 42 (step ST35). The opening 23 is formed by removing a portion of the piezoelectric layer 20 by reactive ion etching (RIE), for example.

The first upper electrode 41 and the second upper electrode 42 are formed on the first main surface 20a of the piezoelectric layer 20, and the overlapping electrode 44 is formed on the lower electrode 43 in a region that overlaps the opening 23 (step ST36). The first upper electrode 41, the second upper electrode 42, and the overlapping electrode 44 are formed by, for example, a vapor deposition lift-off method. In the present example embodiment, the overlapping electrode 44 is formed to have an area larger than the area of the opening 23 of the piezoelectric layer 20. The overlapping electrode 44 is formed simultaneously in the same step as the first upper electrode 41 and the second upper electrode 42. This reduces or prevents the potential difference between the first and second upper electrodes 41 and 42 and the lower electrode 43 that occurs during the film formation of the first upper electrode 41 and the second upper electrode 42.

Next, the front surface electrode 45 is formed on the first extension portion 41b of the first upper electrode 41, and the front surface electrode 46 is formed on the second extension portion 42b of the second upper electrode 42. In addition, in the same step, the front surface electrode 47 is formed on the overlapping electrode 44 (step ST37). The front surface electrodes 45, 46, and 47 are formed by, for example, a vapor deposition lift-off method.

In the present example embodiment, the front surface electrode 47 that overlaps the overlapping electrode 44 is formed simultaneously in the same step as the front surface electrodes 45 and 46 that overlap the first upper electrode 41 and the second upper electrode 42. In this step, when the front surface electrodes 45 and 46 are formed, the overlapping electrode 44 is also exposed to the atmosphere on the first main surface 20a side of the piezoelectric layer 20. With this configuration, even when a certain potential occurs in the first upper electrode 41 and the second upper electrode 42 during the film formation of the front surface electrodes 45 and 46, the same or substantially the same potential occurs also in the lower electrode 43 as in the first upper electrode 41 and the second upper electrode 42 because the front surface electrode 47 is formed on the overlapping electrode 44. Thus, in the manufacturing method of the present example embodiment, it is possible to reduce or prevent the potential difference between the first and second upper electrodes 41 and 42 and the lower electrode 32 that occurs during the film formation of the front surface electrodes 45 and 46.

Next, the sacrificial layers 51 and 52 are removed, so that the first cavity portion 15 and the second cavity portion 16 are formed in the insulating layer 12 (step ST38). This step forms the membrane structures of the piezoelectric layer 20.

The acoustic wave device 10H according to the sixth modification of the third example embodiment is manufactured through these steps described above. The steps illustrated in FIG. 16 are merely a schematic illustration and can be changed as appropriate. In addition, the acoustic wave device 10G (see FIG. 14) according to the third example embodiment described above can be manufactured in steps the same as or similar to those illustrated in FIG. 16. Specifically, the acoustic wave device 10G according to the third example embodiment can be manufactured in the process excluding the steps for forming the front surface electrodes 45, 46, and 47 and the back surface electrode 48 from FIG. 16.

In the acoustic wave device 10H according to the sixth modification, either the front surface electrodes 45, 46, and 47 or the back surface electrode 48 may be omitted. For example, a configuration in which the front surface electrodes 45, 46, and 47 are provided and the back surface electrode 48 is not provided is possible. Alternatively, a configuration in which the front surface electrodes 45, 46, and 47 are not provided and the back surface electrode 48 is provided is also possible.

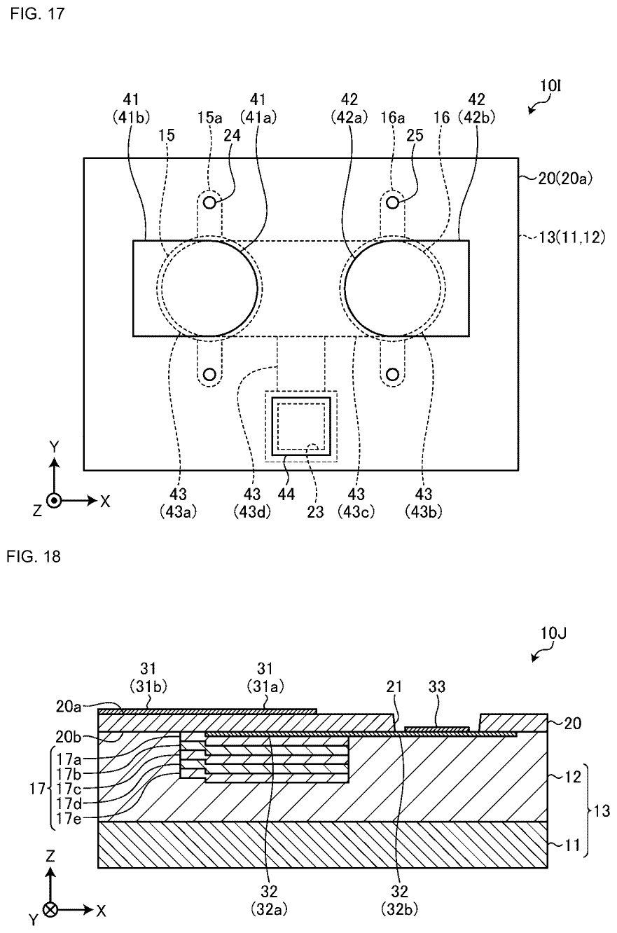

FIG. 17 is a plan view of an acoustic wave device according to a seventh modification of the third example embodiment. As illustrated in FIG. 17, the acoustic wave device 10I according to the seventh modification is different from the third example embodiment and the sixth modification described above in that the lower electrode 43 includes a routing electrode portion 43d.

The routing electrode portion 43d of the lower electrode 43 is coupled to the coupling portion 43c provided in a region between the first upper electrode 41 and the second upper electrode 42 and extends in the Y direction. The opening 23 and the overlapping electrode 44 are provided at a position overlapping the routing electrode portion 43d of the lower electrode 43. In the seventh modification illustrated in FIG. 17, the position of the opening 23 and the overlapping electrode 44 in the Y direction is shifted from the first upper electrode 41 and the second upper electrode 42.

This configuration in the seventh modification increases the degree of freedom of the positions, shapes, and the like of the opening 23 and the overlapping electrode 44. Specifically, even in the case in which the distance between the first upper electrode 41 and the second upper electrode 42 is short, the planar areas of the opening 23 and the overlapping electrode 44 can be ensured. Thus, regardless of the positional relationship between the first upper electrode 41, the second upper electrode 42, and the lower electrode 43, the potential difference between the first and second upper electrodes 41 and 42 and the lower electrode 43 can be reduced or prevented favorably.

The configuration of the routing electrode portion 43d illustrated in FIG. 17 is a mere example, and can be changed as appropriate. For example, the routing electrode portion 43d is not limited to a straight line shape and may include a bent or curved portion. The third example embodiment and each modification illustrated in FIGS. 13 to 17 are based on configurations in which two resonators are provided on the support 13, but are not limited to these configurations. A configuration in which three or more resonators are provided on the support 13 and they are electrically coupled to one another is also possible.

FIG. 18 is a cross-sectional view of an acoustic wave device according to a fourth example embodiment of the present invention. As illustrated in FIG. 18, the acoustic wave device 10J according to the fourth example embodiment is different from the first example embodiment described above in that it includes an acoustic multilayer film 17, instead of the cavity portion 14. Specifically, the acoustic wave device 10 of the first example embodiment includes the cavity portion 14 in the support 13 (the insulating layer 12) and has a membrane structure in which the cavity portion 14 (the hollow portion) is provided on the second main surface 20b side of the piezoelectric layer 20, but the present invention is not limited to this configuration.

As illustrated in FIG. 18, the acoustic multilayer film 17 is laminated on the second main surface 20b of the piezoelectric layer 20. The acoustic multilayer film 17 has a lamination structure including low-acoustic-impedance layers 17a, 17c, and 17e having relatively low acoustic impedance and high-acoustic-impedance layers 17b and 17d having relatively high acoustic impedance. The low-acoustic-impedance layers 17a, 17c, and 17e are, for example, SiO₂ layers, and the high-acoustic-impedance layers 17b and 17d are, for example, metal layers including W, Pt, or the like or dielectric layers including AlN, SiN, or the like. The use of the acoustic multilayer film 17 enables bulk acoustic waves to be confined in the piezoelectric layer 20 without the cavity portion 14.

In the acoustic multilayer film 17, the number of laminated layers such as the low-acoustic-impedance layers 17a, 17c, and 17e and the high-acoustic-impedance layers 17b and 17d is not particularly limited. At least one layer of the high-acoustic-impedance layers 17b or 17d only needs to be located farther from the piezoelectric layer 20 than the low-acoustic-impedance layer 17a, 17c, or 17e.

The low-acoustic-impedance layers 17a, 17c, and 17e and the high-acoustic-impedance layers 17b and 17d may be made of appropriate materials as long as the above-described acoustic-impedance relationship is satisfied. Examples of the material of the low-acoustic-impedance layers 17a, 17c, and 17e include silicon oxide or silicon oxynitride. Examples of the material of the high-acoustic-impedance layers 17b and 17d include alumina, silicon nitride, or metals.

The acoustic multilayer film 17 illustrated in the fourth example embodiment can be combined with each example embodiment and modification described above.

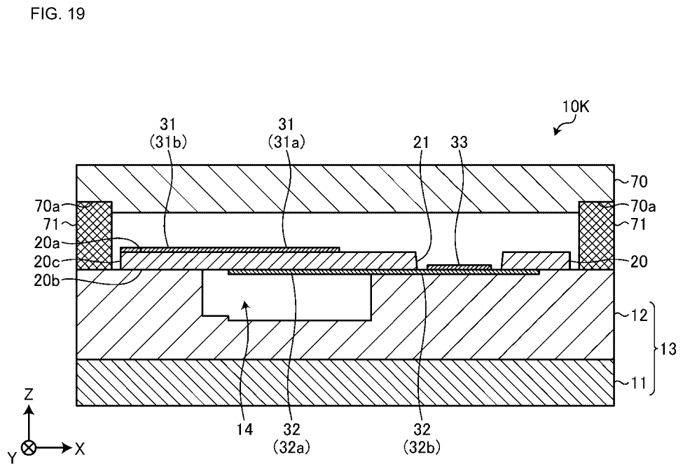

FIG. 19 is a cross-sectional view of an acoustic wave device according to a fifth example embodiment of the present invention. As illustrated in FIG. 19, the acoustic wave device 10K according to the fifth example embodiment is different from the example embodiments and modifications described above in that it includes a lid portion 70 and a joining portion 71.

The lid portion 70 faces the first main surface 20a of the piezoelectric layer 20. The joining portion 71 is provided between the lid portion 70 and the insulating layer 12 of the support 13. Specifically, the piezoelectric layer 20 is not provided on the outer edge side of the support 13. That is, the side surface 20c of the piezoelectric layer 20 on the outer edge side is positioned on the inner side of (closer to the cavity portion 14 than) the side surface of the insulating layer 12. On the outer edge side of the insulating layer 12, the joining portion 71 and the insulating layer 12 are in direct contact with each other and joined together. The side surface 20c of the piezoelectric layer 20 on the outer edge side are located away from the side surface of the support 13.

The joining portion 71 is made of the same material as the insulating layer 12, for example, an insulating material such as silicon oxide (SiO₂). This configuration provides better adhesion between the insulating layer 12 and the joining portion 71, thus improving the sealing properties, as compared with cases in which the material of the joining portion 71 is different from that of the insulating layer 12 (for example, a metal material or the like).

The lid portion 70 includes a recessed portion 70a on the surface facing the first main surface 20a of the piezoelectric layer 20. The recessed portion 70a is configured such that the outer edge side is thinner than the center portion in the lid portion 70. The joining portion 71 is joined to the recessed portion 70a of the lid portion 70. This configuration increases the joint area between the joining portion 71 and the lid portion 70, as compared with cases in which the recessed portion 70a is not provided, thus improving the joint strength.

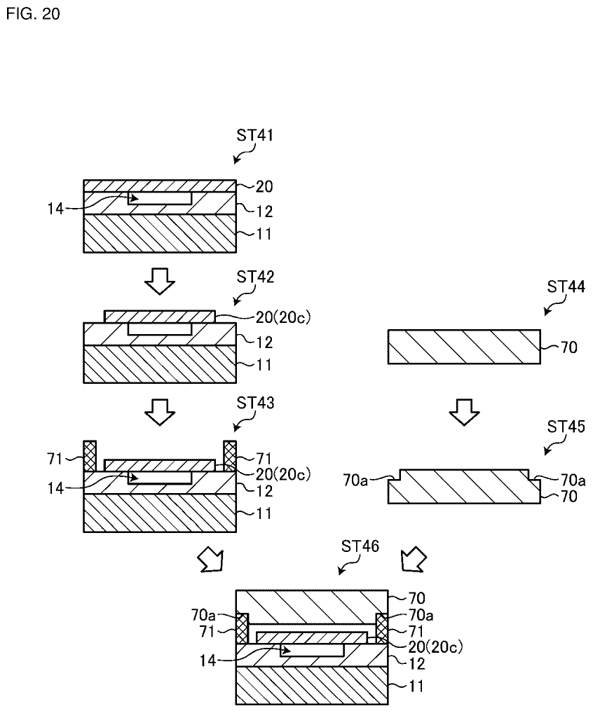

FIG. 20 is an explanatory diagram for explaining an example of a method of manufacturing the acoustic wave device according to the fifth example embodiment. In FIG. 20, for ease of understanding of the drawing, illustration of the upper electrode 31, the lower electrode 32, the overlapping electrode 33, and the opening 21 is omitted.

As illustrated in FIG. 20, a multilayer body including the support substrate 11, the insulating layer 12, and the piezoelectric layer 20 and including the membrane structure is formed (step ST41). The configuration including the support substrate 11, the insulating layer 12, and the piezoelectric layer 20 illustrated in step ST41 can use one of the example embodiments and modifications described above.

Next, a portion of the piezoelectric layer 20 on the outer edge side is removed (step ST42). The portion of the piezoelectric layer 20 on the outer edge side is removed by, for example, RIE. This step exposes the insulating layer 12 in the region on the outer side of the side surface 20c of the piezoelectric layer 20.

The joining portion 71 is formed on the insulating layer 12 on the outer edge side of the insulating layer 12 (step ST43). Since the joining portion 71 is made of the same insulating material as the insulating layer 12, the adhesion between the joining portion 71 and the insulating layer 12 is excellent, and the sealing properties are favorable.

In a step of forming the lid portion 70, the lid portion 70 having a flat plate shape is prepared (step ST44). The lid portion 70 is made of, for example, the same material as the support substrate 11, such as silicon (Si) or quartz crystal.

The recessed portion 70a is formed on the outer edge side of one surface of the lid portion 70 (step ST45). The recessed portion 70a is provided in a region where the lid portion 70 and the joining portion 71 are to be joined together. The lid portion 70 is formed by, for example, dry etching such as RIE.

Next, the joining portion 71 and the recessed portion 70a of the lid portion 70 are joined together (step ST46). This step joins the multilayer body including the membrane structure (the support substrate 11, the insulating layer 12, and the piezoelectric layer 20) and the lid portion 70 with the joining portion 71 interposed therebetween.

An insulating film made of the same insulating material as the joining portion 71 (for example, SiO₂) may be formed on the surface of the lid portion 70 facing the first main surface 20a of the piezoelectric layer 20 and the recessed portion 70a. In this case, the joining portion 71 is joined to the insulating film provided on the lid portion 70, thus improving the sealing properties between the lid portion 70 and the joining portion 71.

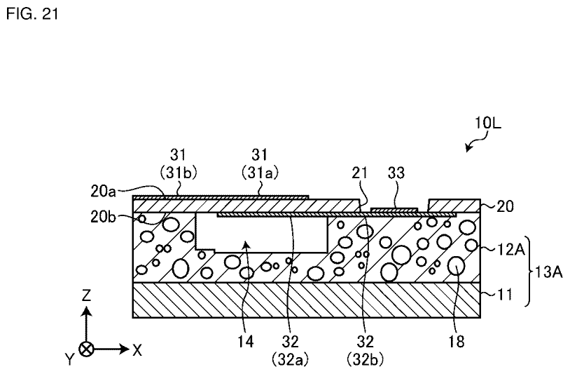

FIG. 21 is a cross-sectional view of an acoustic wave device according to a sixth example embodiment of the present invention. As illustrated in FIG. 21, the acoustic wave device 10L according to the sixth example embodiment is different from the example embodiments and modifications described above in that the insulating layer 12A of the support 13A is a porous film including a large number of pores 18. The pores 18 in FIG. 21 are exaggerated for ease of understanding of the drawing.

The insulating layer 12A is made of one of various kinds of oxide materials such as, for example, yttria (Y₂O₃) and alumina (Al₂O₃). The porous film can be formed by, for example, a thermal spraying method, a plating method, or a method in which a mixed material of an oxide material to be left as a porous film and an organic material is deposited as a film by sputtering and then heated at a high temperature to remove the organic material, leaving only the oxide material.

Since the insulating layer 12A is a porous film in the present example embodiment, thermal stress between the support substrate 11 and the membrane structure of the piezoelectric layer 20 is relaxed, and thus warpage and deformation of the membrane structure of the piezoelectric layer 20 can be reduced. This configuration stabilizes the piezoelectric characteristics of the acoustic wave device 10L, providing improved device characteristics. Since the insulating layer 12A is made of an inorganic material, irreversible positional deviation between the piezoelectric layer 20 and the support substrate 11 due to thermal stress can also be reduced or prevented.

In addition, the support substrate 11 is made of, for example, silicon (Si) and has semiconductive properties. Thus, parasitic capacitance is generated between the support substrate 11 and the upper and lower electrode 31 and 32 and between the support substrate 11 and routing wiring. Since the insulating layer 12A is a porous film in the present example embodiment, the effective dielectric constant is reduced, and the parasitic capacitance can be reduced without increasing the thickness of the insulating layer 12A.

In the present example embodiment, for example, a silicon nitride (SiN) film may be provided between the insulating layer 12A, which is a porous film, and the piezoelectric layer 20. This reduces or prevents moisture ingress through the insulating layer 12A which is a porous film.

In the present example embodiment, the insulating layer 12A may be made of, for example, a material in which —O—Si—O—Si— . . . —Si—O—Si—O— skeletons are formed and a resin is disposed between the skeletons, instead of the porous film.

In this insulating layer 12A, since a resin is disposed between the —O—Si—O—Si— . . . —Si—O—Si—O— skeletons, thermal stress caused by the difference in the coefficient of linear expansion between the support substrate 11 and the piezoelectric layer 20 is relaxed, and this reduces or prevents the amount of warpage and deformation in the membrane structure of the piezoelectric layer 20. This configuration stabilizes the piezoelectric characteristics of the acoustic wave device 10L, providing improved device characteristics. In addition, the —O—Si—O—Si— . . . —Si—O—Si—O— skeletons restrain the support substrate 11 and the piezoelectric layer 20, thus reducing or preventing irreversible positional deviation between the piezoelectric layer 20 and the support substrate 11 caused by thermal stress.

The insulating layer 12A illustrated in the present example embodiment can be combined with each example embodiment and modification described above.

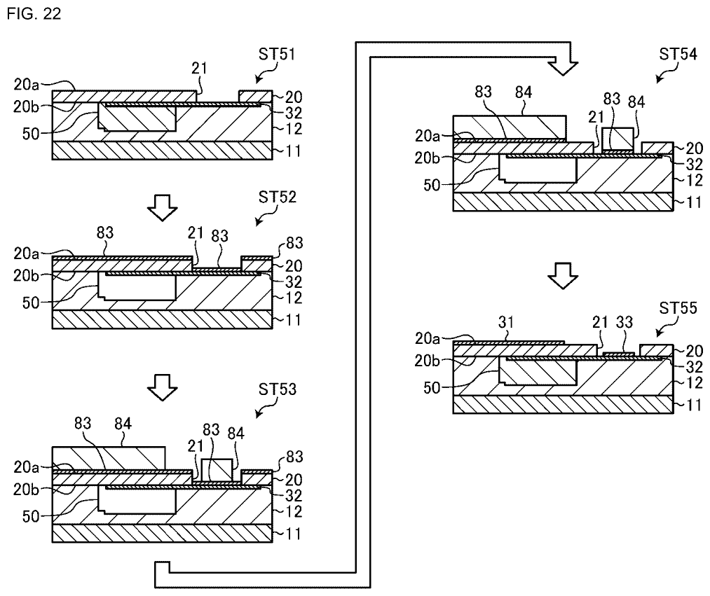

FIG. 22 is an explanatory diagram for explaining an example of a method of manufacturing an acoustic wave device according to an eighth modification of the first example embodiment. The method of manufacturing the acoustic wave device according to the eighth modification is different from the first example embodiment described above (see FIG. 3) in that the upper electrode 31 and the overlapping electrode 33 in steps ST7 to ST9 are formed by a dry process, for example. In the eighth modification, step ST51 corresponds to step ST6 in FIG. 3. In addition, although illustration is omitted in FIG. 22, the eighth modification also includes the same or similar steps as steps ST1 to ST5 and ST10 in FIG. 3.

As illustrated in FIG. 22, as in the above-described step ST6, after the step (step ST51) in which the opening 21 is formed in the piezoelectric layer 20, a film of a metal layer 83 is formed on the entire or substantially the entire surface of the piezoelectric layer 20 (step ST52). The metal layer 83 is provided to extend over the first main surface 20a of the piezoelectric layer 20 and the lower electrode 32 in the region that overlaps the opening 21. Also in the eighth modification, simultaneously with forming the metal layer 83 as the upper electrode 31, the metal layer 83 defining and functioning as the overlapping electrode 33 is formed as a film on the lower electrode 32 in the region that overlaps the opening 21.

Next, a pattern of a resist 84 is formed on the metal layer 83 by, for example, photolithography (step ST53). In this step, the resist 84 is formed in the region where the upper electrode 31 is to be formed and in the region where the overlapping electrode 32 is to be formed in a region that overlaps the opening 21.

Next, the portions of the metal layer 83 not covered with the resist 84 are removed by, for example, dry etching (step ST54). Thereafter, the resist 84 is removed, and the metal layer 83 in the portions overlapping the resist 84 forms the upper electrode 31 and the overlapping electrode 33 (step ST55). As described above, the present example embodiment uses the dry process to form the upper electrode 31 on the first main surface 20a of the piezoelectric layer 20 and the overlapping electrode 33 on the lower electrode 32 in a region that overlaps the opening 21.

The example embodiments and modifications thereof described above are to facilitate understanding of the present invention and are not intended to limit the interpretation of the present invention. The present invention can be changed or improved without departing from the spirit and scope thereof, and the present invention also includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface opposite to the first main surface;
an upper electrode on the first main surface of the piezoelectric layer;
a lower electrode on the second main surface of the piezoelectric layer; and
a support facing the second main surface of the piezoelectric layer; wherein
the piezoelectric layer includes an opening extending through the piezoelectric layer in a thickness direction in a region that overlaps the lower electrode and does not overlap the upper electrode; and
the acoustic wave device further includes an overlapping electrode on the lower electrode in a region that overlaps the opening and including a same material as the upper electrode.

2. The acoustic wave device according to claim 1, wherein an area of the overlapping electrode is smaller than an area of the opening.

3. The acoustic wave device according to claim 1, wherein
the upper electrode includes a first upper electrode and a second upper electrode spaced apart from the first upper electrode;
the lower electrode extends over a region that overlaps the first upper electrode, a region that overlaps the second upper electrode, and a region between the first upper electrode and the second upper electrode;
the lower electrode includes a routing electrode portion coupled to a region between the first upper electrode and the second upper electrode; and
the opening and the overlapping electrode are located at a position overlapping the routing electrode portion of the lower electrode.

4. The acoustic wave device according to claim 1, wherein
the piezoelectric layer includes single-crystal lithium niobate or single-crystal lithium tantalate; and
a thickness of the piezoelectric layer is about 1 μm or less.

5. The acoustic wave device according to claim 1, further comprising an intermediate conductive layer between the lower electrode and the overlapping electrode in a region that overlaps the opening.

6. The acoustic wave device according to claim 1, wherein
the upper electrode includes a first upper electrode and a second upper electrode spaced apart from the first upper electrode;
the lower electrode extends over a region that overlaps the first upper electrode, a region that overlaps the second upper electrode, and a region between the first upper electrode and the second upper electrode; and
the opening and the overlapping electrode are located in a region that overlaps the lower electrode and is between the first upper electrode and the second upper electrode.

7. The acoustic wave device according to claim 1, wherein
an area of the overlapping electrode is larger than an area of the opening; and
the overlapping electrode is on the lower electrode in a region that overlaps the opening, and extends along an inner wall of the opening and onto the first main surface of the piezoelectric layer.

8. The acoustic wave device according to claim 7, further comprising:
an interlayer insulating layer covering an outer edge of the opening; wherein
the interlayer insulating layer is between the inner wall of the opening and the overlapping electrode and between the first main surface of the piezoelectric layer and the overlapping electrode.

9. The acoustic wave device according to claim 1, further comprising front surface electrodes respectively overlapping the overlapping electrode and a portion of the upper electrode.

10. The acoustic wave device according to claim 1, further comprising a back surface electrode between the lower electrode and the support in a region that overlaps the opening.

11. The acoustic wave device according to claim 1, further comprising a hollow portion on a surface of the support facing the second main surface of the piezoelectric layer in a region where the upper electrode and the lower electrode face each other.

12. The acoustic wave device according to claim 1, further comprising:
an acoustic reflection film including a high-acoustic-impedance layer having relatively high acoustic impedance and a low-acoustic-impedance layer having relatively low acoustic impedance; wherein
the acoustic reflection film is on a surface of the support facing the second main surface of the piezoelectric layer in a region where the upper electrode and the lower electrode face each other.

13. The acoustic wave device according to claim 1, wherein the support includes a support substrate and an insulating layer between the support substrate and the piezoelectric layer.

14. The acoustic wave device according to claim 13, wherein the support substrate includes silicon or quartz crystal.

15. The acoustic wave device according to claim 13, wherein the insulating layer includes silicon oxide.

16. The acoustic wave device according to claim 1, wherein the piezoelectric layer includes etching openings.

17. The acoustic wave device according to claim 1, wherein each of the upper electrode and the lower electrode includes aluminum, platinum, copper, tungsten, or molybdenum, or an alloy including at least one of aluminum, platinum, copper, tungsten, or molybdenum.

18. The acoustic wave device according to claim 1, wherein the overlapping electrode includes aluminum, platinum, copper, tungsten, or molybdenum, or an alloy including at least one of aluminum, platinum, copper, tungsten, or molybdenum.

19. The acoustic wave device according to claim 1, further comprising:
front surface electrodes respectively overlapping the overlapping electrode and a portion of the upper electrode; and
a back surface electrode between the lower electrode and the support in a region that overlaps the opening.

20. The acoustic wave device according to claim 1, the support includes a first hollow portion and a second hollow portion spaced apart from the first hollow portion.
